(19) United States
(12) Patent Application Publication
(10) Pub. No.: US 2008/0203581 A1
(43) Pub. Date: Aug. 28, 2008

(54) INTEGRATED CIRCUIT

(75) Inventors: Jochen Thomas, Muenchen (DE); Wolfgang Hetzel, Nattheim (DE); Mathias Grumm, Berlin (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/679,594

(22) Filed: Feb. 27, 2007

(51) Int. Cl. H01L 23/52; H01L 21/50

(52) U.S. Cl. 257/777; 438/107; 257/E23.141; 257/E21.499

(57) ABSTRACT

An integrated circuit is disclosed. In one embodiment, the integrated circuit includes a first interface layer on a first substrate, the first interface layer including a first signal path, a second interface layer on the first interface layer, the second interface layer including a second signal path, the second signal path being coupled to the first signal path, and a second substrate on the second interface layer. In one embodiment, the second substrate includes an electronic device, the electronic device being coupled to the second signal path of the second interface layer.

### BACKGROUND

Demands imposed on large scale integrated circuits, such as electronic memory devices, micro-processors, signal processors, and integrated logic devices, are constantly increasing. In the case of the electronic memory devices, that demands mainly translate into increasing access speed and into enlarging storage capacity. As far as modern memory devices are concerned, the computer industry has established, amongst others, the so-called DRAM (Dynamic Random Access Memory) as economic means for high-speed and high-capacity data storage.

Although a DRAM requires continuous refreshing of the stored information, speed and information density, combined with a relatively low cost, have put the DRAM to a pivotal position in the field of information technology. Almost every type of computer system, ranging, for example, from PDAs over notebook computers and personal computers to high-end servers, takes advantage of this economic and fast data storage technology. Besides the DRAM, the computer industry develops alternatives, such as phase change RAM (PCRAM), conductive bridging RAM (CBRAM), and magneto-resistive RAM (MRAM). Other concepts include the so-called flash RAM or static RAM (SRAM).

In order to increase the storage capacity of, for example, a memory device, identical memory chips, including a memory array, are stacked. Such a stack of one or more chips may be packaged such to form a discrete memory device. Conventional methods also apply the so-called flip chip technology, wherein a chip is flipped and mounted upside down on a carrier substrate or another chip. Upon stacking more than one chip to form a stack of chips, several issues may be of importance and act as a base for considerable improvements. For example, interstitial layers between the single chips may realized as thin as possible, in order to achieve a minimum overall stack height and/or allow for an optimized heat coupling and flow.

By providing two identical chips with appropriate re-distribution layers, it may be hence possible to connect a first chip with a first re-distribution layer to a carrier substrate, for example, by bonding, such as wirebonding. A second chip with a second re-distribution layer is then flipped and mounted upside down on the first chip. A connection between the two re-distribution layers then allows for a signal routing from the second chip through the second re-distribution layer and the first re-distribution layer to the carrier substrate. For this connection, contact pads may be used, which are already present on a re-distribution layer, for example a test pad. Such a test pad is used for testing the chip prior to packaging. Avoiding additional pads and signal lines may advantageously reduce input capacitance. The minimum distance between the two chips is then given by the height of the two re-distribution layers and may be additionally influenced by the diameter of a bond wire. This may represent a minimum of space, while still allowing for connection of both chips. This may further allow for a minimum stack height. Furthermore, a spacer chip or a spacer film may be rendered obsolete.

For these and other reasons, there is a need for the present invention.

### SUMMARY

One embodiment provides an integrated circuit. The integrated circuit having a first substrate, a first interface layer on the first substrate, the first interface layer includes a first signal path, a second interface layer on the first interface layer, the second interface layer including a second signal path, the second signal path being coupled to the first signal path. One embodiment provides a second substrate on the second interface layer, the second substrate including an electronic device, the electronic device being coupled to the second signal path of the second interface layer.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A through 1I illustrate schematic views of an integrated circuit in various stages during fabrication, according to a first embodiment of the present invention.

FIGS. 2A through 2C illustrate schematic views of an integrated circuit in various stages during fabrication, according to a second embodiment of the present invention.

FIGS. 3A through 3C illustrate schematic views of an integrated circuit in various stages during fabrication, according to a third embodiment of the present invention.

FIGS. 4A and 4B illustrate schematic views of an integrated circuit in various stages during fabrication, according to a fourth embodiment of the present invention.

FIG. 5 illustrates a schematic view of an integrated circuit, according to a fifth embodiment of the present invention.

FIG. 6A through 6D illustrate schematic views of an integrated circuit in various stages during fabrication, according to a sixth and seventh embodiment of the present invention.

FIGS. 7A and 7B illustrate schematic views of an interface layer, according to an eighth embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Various embodiments of the present invention may provide particular advantages for an improved integrated circuit, an improved memory device, an improved memory module, an improved circuit system, or an improved method of fabricating an integrated circuit.

In one embodiment of the present invention an integrated circuit is provided which includes a first substrate; a first interface layer on the first substrate, the first interface layer including a first signal path; a second interface layer on the first interface layer, the second interface layer including a second signal path, the second signal path being coupled to the first signal path; a second substrate on the second interface layer, the second substrate including an electronic device, the electronic device being coupled to the second signal path of the second interface layer.

Accordingly a memory device, a memory module, a circuit system, and a method of fabricating an integrated circuit are provided as embodiments of the present invention.

According to an embodiment of the present invention an integrated circuit includes a first substrate; a first interface layer on the first substrate, the first interface layer including a first signal path; a second interface layer on the first interface layer, the second interface layer including a second signal path, the second signal path being coupled to the first signal path; a second substrate on the second interface layer, the second substrate including an electronic device, the electronic device being coupled to the second signal path of the second interface layer.

According to an another embodiment of the present invention a memory device includes a first substrate; a first interface layer on the first substrate, the first interface layer including a first signal path; a second interface layer on the first interface layer, the second interface layer including a second signal path, the second signal path being coupled to the first signal path; a second substrate on the second interface layer, the second substrate including an electronic device, the electronic device being coupled to the second signal path of the second interface layer.

According to a yet another embodiment of the present invention a memory module includes a circuit board and a memory device, wherein the memory device includes a first substrate on the circuit board; a first interface layer on the first substrate, the first interface layer including a first signal path; a second interface layer on the first interface layer, the second interface layer including a second signal path, the second signal path being coupled to the first signal path; and a second substrate on the second interface layer, the second substrate including an electronic device, the electronic device being coupled to the second signal path of the second interface layer, wherein the first signal path is coupled to the circuit board.

According to a yet another embodiment of the present invention a circuit system includes an integrated circuit and a circuit board, wherein the integrated circuit includes a first substrate on the circuit board; a first interface layer on the first substrate, the first interface layer including a first signal path; a second interface layer on the first interface layer, the second interface layer including a second signal path, the second signal path being coupled to the first signal path; and a second substrate on the second interface layer, the second substrate including an electronic device, the electronic device being coupled to the second signal path of the second interface layer, wherein the first signal path being coupled to the circuit board.

According to a yet another embodiment of the present invention a method of fabricating an integrated circuit includes providing a first substrate; providing a first interface layer on the first substrate, the first interface layer including a first signal path; providing a second substrate, the second substrate including an electronic device; providing a second interface layer on the second substrate, the second interface layer including a second signal path, the second signal path being coupled to the electronic device of the second substrate; stacking the first substrate with the first interface layer and the second substrate with the second interface layer, such that the first interface layer is arranged on the second interface layer; and establishing a contact between the first signal path and the second signal path.

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit equally effective embodiments.

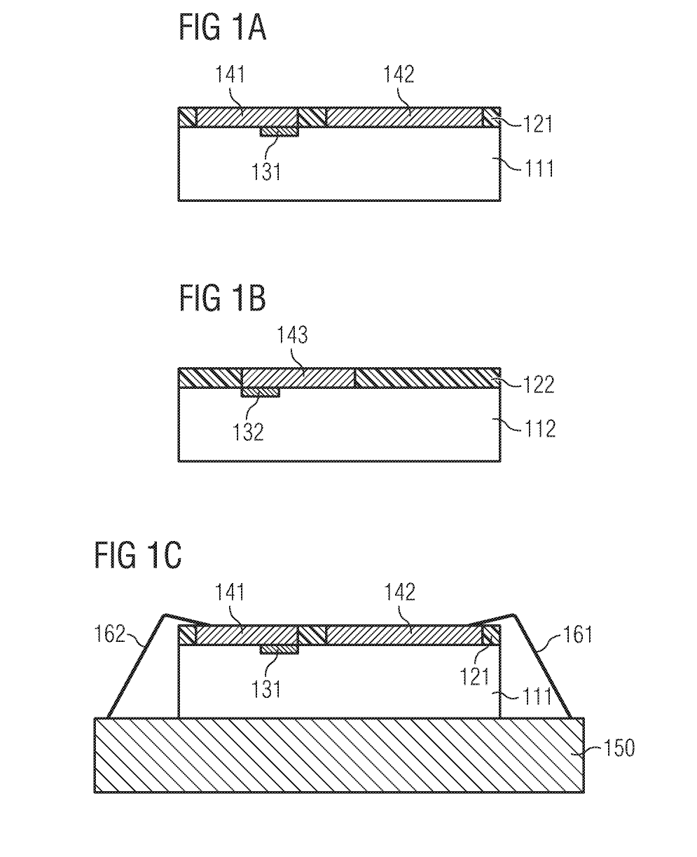

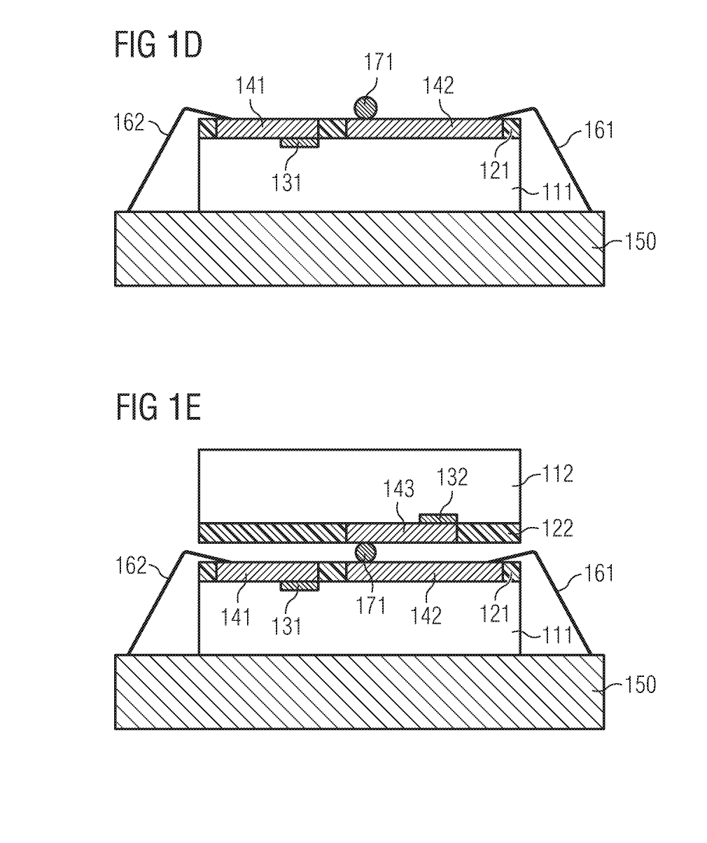

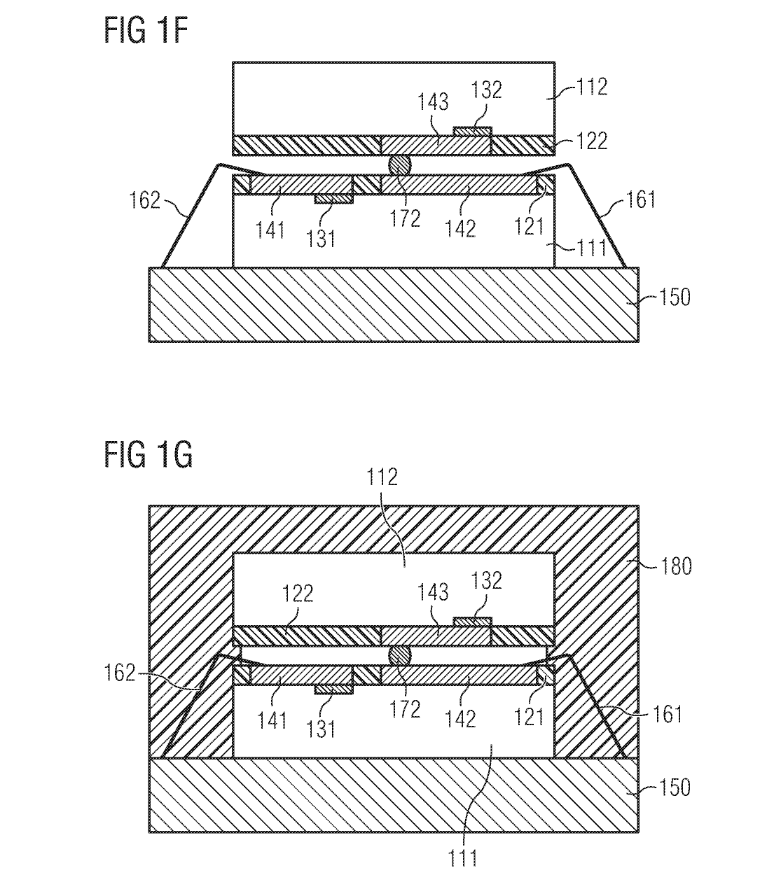

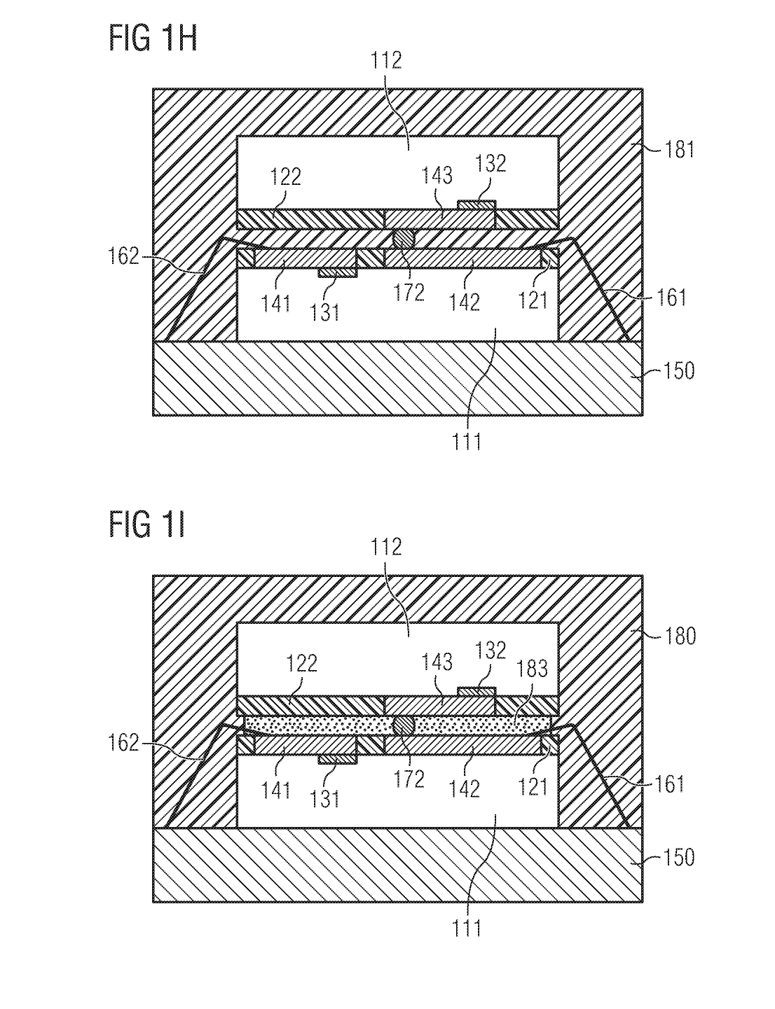

FIG. 1A through FIG. 1I illustrate schematic views of an integrated circuit in various stages during fabrication, according to a first embodiment of the present invention. FIG. 1A illustrates a first substrate 111 including a first functional entity 131. On the first substrate 111 there is arranged a first interface layer 121, which may include signal lines, such as a first signal line 141 and/or a second signal line 142.

The first substrate 111 may include a semiconductor substrate with an electronic functional entity 131, such as a transistor, resistor, capacitor, conduction line, and/or another electronic entity as known from the manufacturing of integrated circuits. Furthermore, the first substrate 111 may include an optical functional entity 131, such as a light emitter, a light detectors, or a wave guide. The first interface layer 121 includes the signal lines 141 and 142, wherein the first signal line 141 is coupled to the first functional entity 131 of the first substrate 111.

FIG. 1B illustrates a second substrate 112 with a second functional entity 132. The above recited examples for the first substrate 111 and the first entity 131 may also apply to the second substrate 122 and to the second functional entity 132. On the second substrate 112 there is arranged a second interface layer 122, which includes a third signal line 143. According to an embodiment of the present invention, the first substrate 111 and the second substrate 112 may be identical substrates, such as identical chips, memory chips, dies, or integrated circuits.

As illustrated in FIG. 1C, the first substrate 111 with the first interface layer 121 is arranged on a carrier substrate 150. The signal lines 141 and 142 of the first interface layer 121 may be connected to the carrier substrate 150 by connections 161 and 162, respectively. An attachment of the a substrate to the carrier substrate 150 may be effected by a die attach process. The connections 161 and 162 may comprise, for example, a bond wire. Such a bond wire may connect a bond pad at an end of a signal line, such as the signal line 141 or 142, to a respective bond pad on the carrier substrate 150. The carrier substrate 150 may thus further include further signal line and/or a redistribution layer (RDL) for connecting the bond pad to other means for interconnection, such as landing pads, pins, or a ball grid array. The carrier substrate 150 may further include one or more redistribution layers for redistributing signals from a first position on a first surface to a second position on a second surface of the carrier substrate 150.

FIG. 1D illustrates the arrangement of FIG. 1C with a first solder ball 171 for connecting the second signal line 142, the signal line 142 being an electrical signal line according to this embodiment. The solder ball 171 may also be a solder bump. The second signal line 142 may include a contact pad at the position of the first solder ball 171 for connecting to the solder ball 171. The solder ball 171 may include tin, lead, copper, silver, bismuth, and/or other suitable materials, which may wet the contact pad. Additionally, the contact pad or the ball 171 may include a flux, in order to ease the wetting of the solder to the pad. The second signal line 142 may further include means for isolating the second signal line 142 to other entities except the ball 171 and the first connection 161. In a similar way, the first signal line 141 may include means for isolation, nevertheless still allowing for a contact to the first entity 131 and to the second connection 162.

As illustrated in FIG. 1E, the second substrate 112 with the second interface layer 122, as described in FIG. 1B, is arranged upside down on top of the first substrate 111 with the first interface layer 121. The arrangement of the signal lines 142 and 143 is such that the third signal line 143 connects to the ball 171. This arrangement may already suffice to ensure a contact between the second signal line 142 and the third signal line 143. Additionally, the solder ball 171 may be transferred into a solder connection 172, as illustrated in FIG. 1F. This transition may be induced by a heating stage, in which, for example, a fusible material is melted to form the connection 172 to the second signal line 142 and the third signal line 143. The arrangements of FIG. 1E or FIG. 1F may thus provide a continuous connection from the second functional entity 132 of the second substrate 112 over the third signal line 143 of the second interface layer 122, the ball 171 or connection 172, respectively, the second contact line 142 of the first interface layer 121, and the first connection 161 to the carrier substrate 150.

FIG. 1G illustrates the arrangement of FIG. 1F in conjunction with a package 180. It may be noted, that for FIG. 1G through FIG. 1I the connection 172 may also be replaced by the ball 171. The package 180 surrounds, at least partially, the carrier substrate 150, the connections 161, 162, and the substrates 111, 112. The package 180 may include a mould, such as a resin, to enclose and protect the integrated circuit, including the first substrate 111 and the second substrate 112. Protection may be required from the environment, from moisture, from electrical and mechanical shocks, and/or radiation. The package 180 may further enable an easy handling of the device. The package 180 may further surround the carrier substrate 150 in a way that only contacts, such as pins or contact pads protrude from the package 180.

FIG. 1H illustrates an alternative configuration of the integrated circuit, wherein a second package 181 may also be arranged in the space between the first interface layer 121 and the second interface layer 122. The material may be the same as described in conjunction with the package 180 in FIG. 1G. Filling the space between the interface layers 121, 122 may provide a well-defined mechanical, dielectric, electric, or optical environment between the two interface layers. Such a filling may provide a full-area mechanical contact, which may prevent moisture-absorption and/or delamination. Furthermore, the exclusion of any voids may also provide advantages during heating the entire assembly, since gases or liquids present in voids may expand upon heating and give rise to internal mechanical stress. Also, voids may give rise to undesired stray capacities or signal leakage.

In another configuration of the integrated circuit according to the first embodiment of the present invention, as illustrated in FIG. 1I, an intermediate layer 183 may include a filling material and may fill the gap in between the first interface layer 121 and the second interface layer 122. This intermediate layer 183 may include another material different from the package 180, and may be provided by a wafer-level deposition and structuring process. According to this configuration, the material of the intermediate layer 183 may be optimized for the requirements between the interface layers 121 and 122, whereas the material of the package 180 may be optimized for the purpose of packaging the integrated circuit. The filling material, such as the package material 181 between the first interface layer 121 and the second interface layer 122 or the intermediate layer 183 may be provided before placing the second substrate 112 with the second interface layer 122 on the first substrate 111 with the first interface layer 121. The intermediate layer 183 may include materials such as a dielectric material.

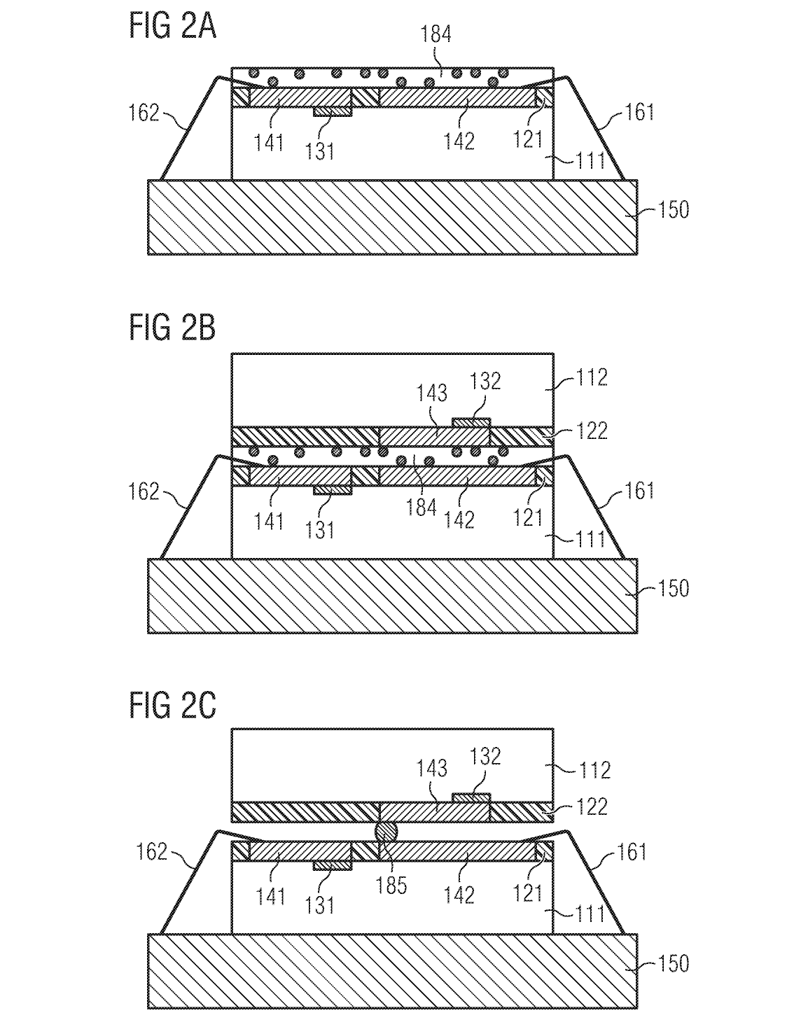

FIGS. 2A through 2C illustrate an integrated circuit in various stages during fabrication, according to a second embodiment of the present invention. The arrangement, as illustrated in FIG. 2A, corresponds mainly to the arrangement, as illustrated and described in conjunction with FIG. 1C, with addition of a solder paste layer 184. According to this second embodiment of the present invention, the solder paste layer 184 is provided on the first interface layer 121. The solder paste layer 184 may include particles of a solder material, such as tin, copper, silver, led, bismuth, and a carrier material, which may include a flux material, such as a resin, colophony, zinc chloride, and/or other common flux materials. According to this embodiment, and as illustrated in FIG. 2B, the second substrate 112 with the second interface layer 112 is arranged upside down on top of the solder paste layer 184, similarly to the arrangement as illustrated and described in conjunction with FIG. 1E.

A heating process, such as a reflow stage, may be used to form a solder connection 185 including the solder material of the soldering paste 184. The interface layers 121 and 122 may include means to ensure a proper and reliable formation of the solder connection 185 from soldering material of the soldering paste 184. For example, the signal lines 142 and 143 may include a contact, such as a contact pad, at the appropriate positions, which may be wetted by the solder material of the soldering paste. In the remainder of the area, however, the signal lines may include means for isolation and/or a solder stop paste. The signal lines 142, 143 may furthermore be arranged at least partially inside the interface layers 121, 122 such to be surrounded by an insolating material except in areas where a desired contact, for example to the functional entities 131, 132, to the connection 185, and/or to connections 161, 162, are to be established.

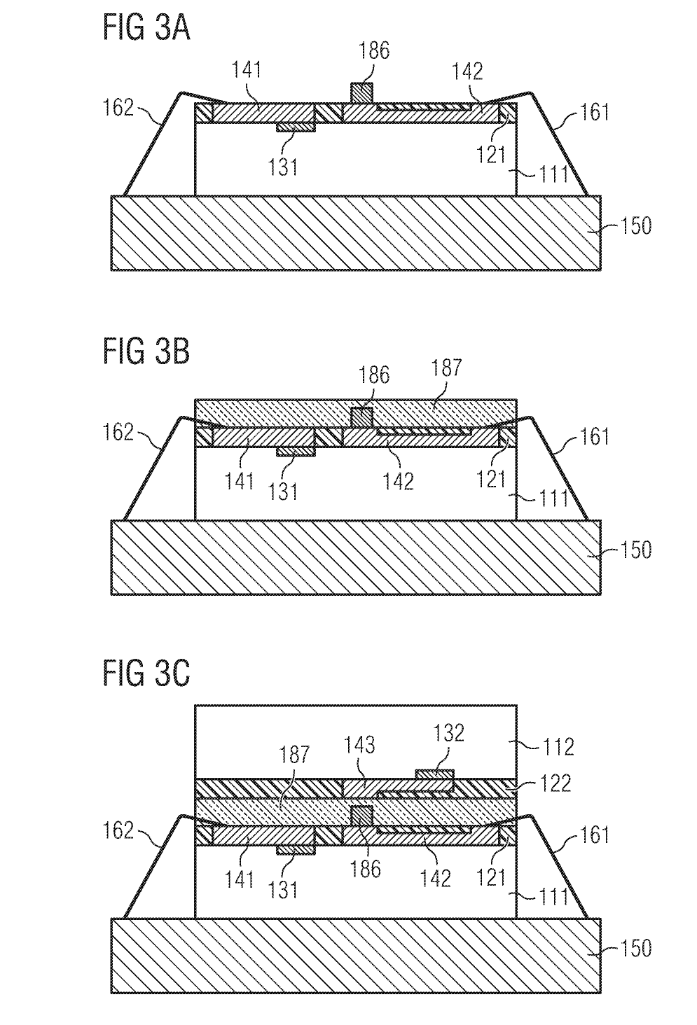

FIGS. 3A through 3C illustrate an integrated circuit in various stages during fabrication, according to a third embodiment of the present invention. The arrangement, as illustrated in FIG. 3A, corresponds mainly to the arrangement, as illustrated and described in conjunction with FIG. 1C, with addition of a stud bump 186. According to this embodiment, the stud bump 186 is arranged on the first interface layer 121. The second signal line 142 may be arranged at least partially inside the first interface layer 121 or may include means for isolation, such to allow for a contact only in an area of the stud bump 186 and in area to connect to the connection 161.

As illustrated in FIG. 3B, a conductive adhesive 187 is provided on the first interface layer 121, which may include a conductive adhesive, an anisotropic conductive adhesive, or a soldering paste. An anisotropic conductive adhesive provides a substantially higher conductivity to signals, such as an electric current, in one direction than perpendicular to that one direction. The usage of conductive adhesive may substantially reduce the thermal budget of the stack of substrate and layers, since processes at elevated temperatures, such as reflow soldering, are rendered obsolete.

As illustrated in FIG. 3C, the second substrate 112 and the second interface layer 122, as already described in conjunction with FIG. 1B, is arranged on the conductive adhesive 187. The third signal line 143 may be arranged at least partially inside the second interface layer 122 or may include means for isolation, such to allow for a contact only in an area of the functional entity 132 and in area to connect to the stud bump 186. A continuous contact may be established between the second functional entity 132 over the third signal line 143, the adhesive layer 187, the stud bump 186, the second signal line 142, and the connection 161 to the carrier substrate 150. In the case that the intermediate layer 187 includes a soldering paste, a heating stage may now be applied in order to solder the stud bump 186 to the third signal line 143. In the case that the intermediate layer 187 includes an anisotropic conductive adhesive, the conductivity of the adhesive is substantially higher in a direction perpendicular to the plane of the interface layer 121, 122, than in a direction which is parallel to the plane of the interface layer 121, 122. In this way, an appropriate coupling may be established between the stud bump 186 and the third signal line 143, whereas a coupling is suppressed toward other entities, such as to the first signal line 141, although said first signal line 141 may not include dedicated means for isolation.

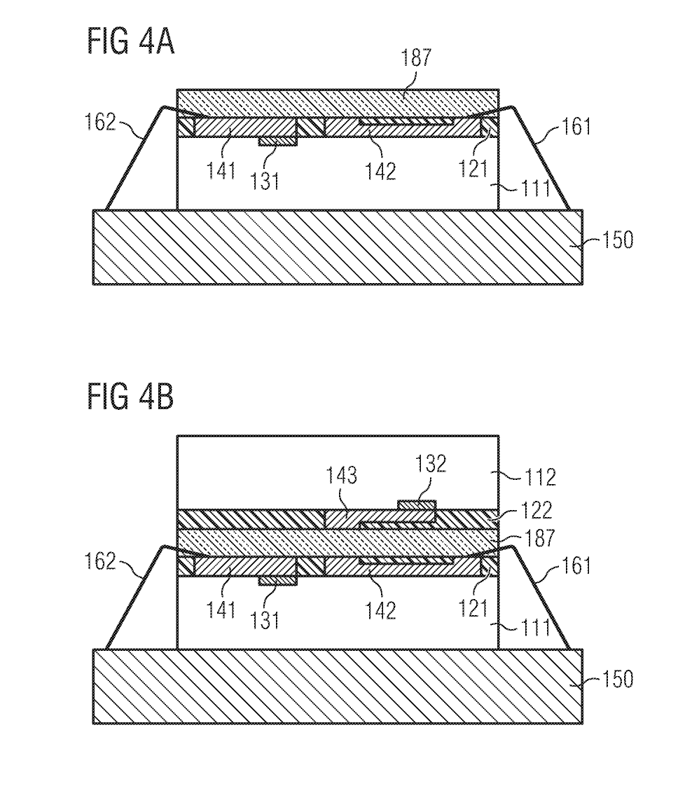

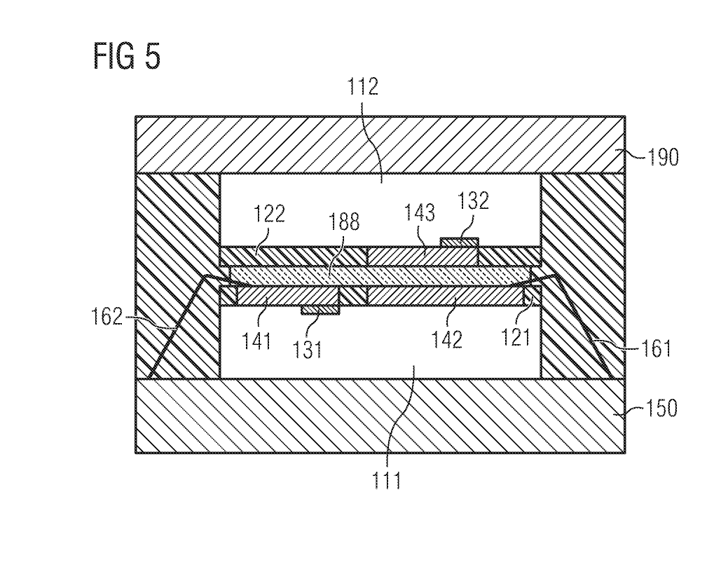

FIGS. 4A and 4B illustrate the integrated circuit according to a fourth embodiment of the present invention. The arrangement, as illustrated in FIG. 4A, corresponds mainly to the arrangement, as illustrated and described in conjunction with FIG. 1C, with addition of the conductive adhesive 187. According to this embodiment, the conductive adhesive 187 is provided on the first interface layer 121, which may include an anisotropic conductive adhesive.

As illustrated in FIG. 4B, the second substrate 112 and the second interface layer 122, as already described in conjunction with FIG. 1B, is arranged on the conductive adhesive 187. The third signal line 143 may be arranged at least partially inside the second interface layer 122 or may include means for isolation, such to allow for a contact only in an area of the functional entity 132 and in area to connect to the second signal line 142. The latter may be achieved by corresponding openings in the interface layer or isolation, such to establish an overlapping area in which the signal lines are exposed and hence may form a contact over the adhesive 187. A continuous contact may be established between the second functional entity 132 over the third signal line 143, the adhesive layer 187, the second signal line 142, and the connection 161 to the carrier substrate 150. In the case that the intermediate layer 187 includes an anisotropic conductive adhesive, the conductivity of the adhesive is substantially higher in a direction perpendicular to the plane of the interface layer 121, 122, than in a direction which is parallel to the plane of the interface layer 121, 122. In this way, an appropriate coupling may be established between the second signal line 142 and the third signal line 143, whereas a coupling is suppressed toward other entities, such as to the first signal line 141, although said first signal line 141 may not include dedicated means for isolation.

Then second signal line 142 is arranged in the first interface layer 121, such that it is isolated from the anisotropic adhesive layer 187 except for an area to contact to the first contact line 161 and an area which at least overlaps with a corresponding area of the third signal line 143 in the second interface layer 122. In this way, the anisotropic conductive adhesive 187 provides a contact between the second signal line 142 and the third signal line 143, while isolating that signal lines from other remaining entities. The signal lines may be further isolated to the facing substrates except for areas and regions where a contact to entities, such as the functional entity 131 or the functional entity 132, is desired.

FIG. 5 illustrates an integrated circuit according to a fifth embodiment of the present invention. According to this embodiment, a stack of substrates 111, 112 and layers 121, 122, 188, is arranged on a carrier substrate 150. The stack of substrates and layers is connected to the carrier substrate 150 by contact lines 161 and 162. Elements being denoted by reference numbers already introduced in the course of this description correspond to elements already being described in conjunction with one of the preceding FIGS. 1A through 4B. In particular, the intermediate layer 188 may be one of the intermediate layers as described in conjunction with the previous embodiments of FIGS. 1A through 4B, and may comprise, therefore, a void, a package material, a resin, a dielectric material, a solder ball, a solder connection, a stud bump, a conductive adhesive, an anisotropic conductive adhesive, and/or soldering paste.

According to this embodiment a heat spreader 190 is arranged on the second substrate 112. The heat spreader 190 may be in direct contact to the second substrate 112 or in contact by an additional layer including an adhesive and/or a heat conductive material. The package 180 may either be capped by the heat spreader 190 or may reach up to the surface of the heat spreader 190. The heat spreader 190 may transport heat from the integrated circuit of the substrates 111 and 112 to an environment or to a heat sink. The heat conductivity of the intermediate layer 188 may furthermore provide a good heat conduction, such that essentially the same temperature is achieved in both substrates 111 and 112. This temperature balance may have further advantages during the operation of the integrated circuit, since temperature dependent properties of the electronic or optic circuits of the substrates 111 and 112 may be compensated for each other. Hence, the functional entities of both substrates 111 and 112 may behave similarly or even identically.

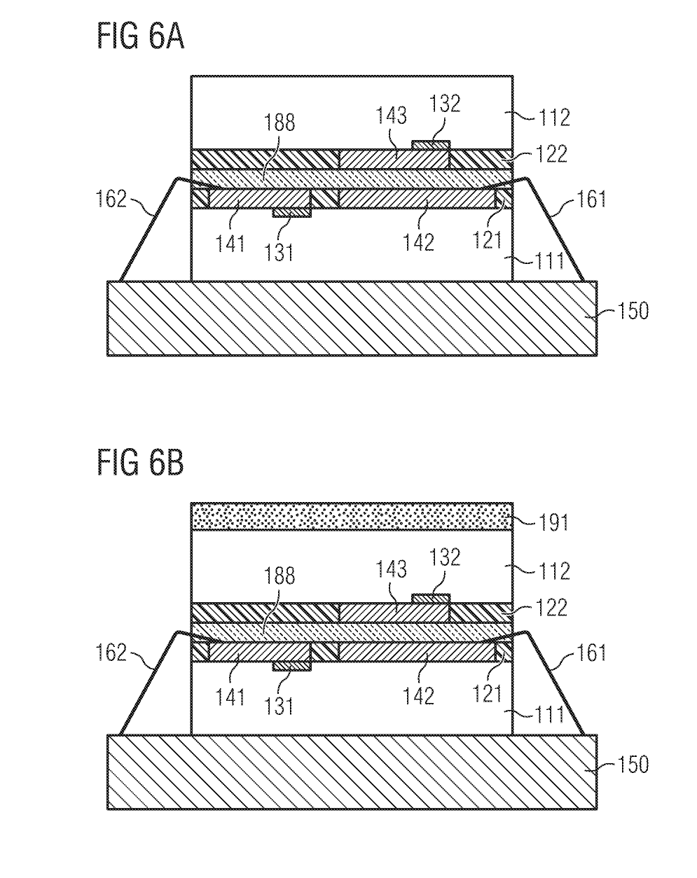

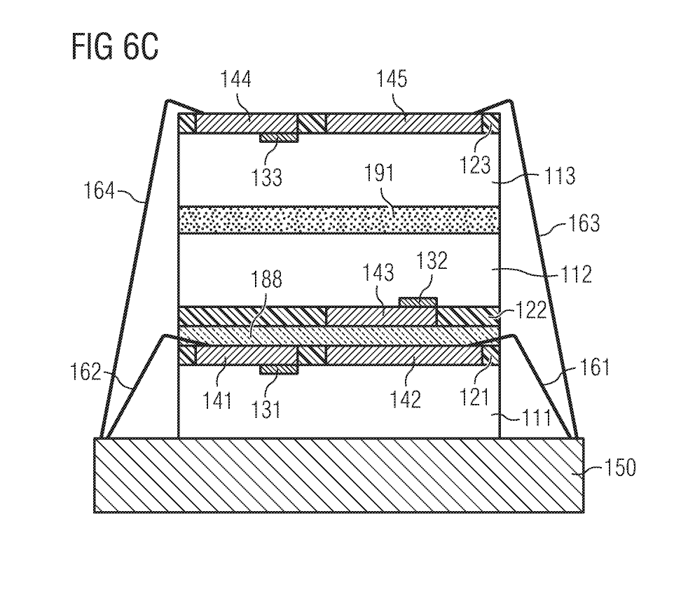

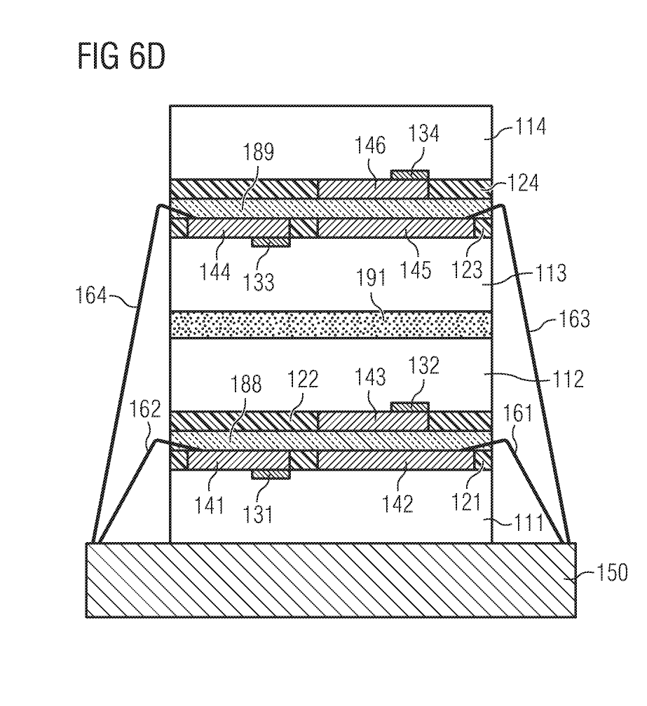

FIG. 6A through 6D illustrate a schematic view of an integrated circuit according to a sixth and seventh embodiment of the present invention. The arrangement as illustrated in FIG. 6A is similar to an arrangement as described in conjunction with one of the previous embodiments of the present invention, such as in conjunction with FIG. 1F, 2C, 3C, or 4B. According to the sixth embodiment of the present invention a sticking layer 191 is arranged on the second substrate 112, as illustrated in FIG. 6B. The sticking layer 191 may include an adhesive, a heat conductive material, a dielectric material, and/or a conductive material.

As illustrated in FIG. 6C, a third substrate 113 and third interface layer 123 are arranged on the sticking layer 191, this arrangement yielding a stack of substrates and layers including three substrates. Similarly to the first interface layer 121, the third interface layer 123 may include contacts, such as bond pads, for connecting to the carrier substrate 150 via a third and a fourth connection 163 and 164, including, for example, bond wire. According to this embodiment of the present invention, a package and/or a heat spreader may now be provided to the integrated circuit to form a ready integrated circuit and/or device including three substrates. The heat spreader benefit may also apply to a stack of two or more substrates, since the minimization of the distance between the substrates also minimizes temperature differences within the stack.

As illustrated in FIG. 6D, the integrated circuit may further include a fourth substrate 114, according to a seventh embodiment of the present invention. According to this embodiment, a second intermediate layer 189 is arranged on top of the arrangement as illustrated and described in conjunction with FIG. 6C. A fourth substrate 114 with a fourth interface layer 124 is then arranged upside down on the second interface layer 189. According to this embodiment, a package and/or a heat spreader may now be provided to the integrated circuit to form a ready integrated circuit and/or device including four substrates. According to an embodiment, the stack of substrates 113, 114 and layers 123, 124 may essentially correspond to the stack of substrates 111, 112 and layers 121, 122. However, the interface layer 123 and/or the interface layer 124 may take into account the presence of the connections 160 and 161, and may require a displacement of contact areas in respect to the layers 121, 122.

Furthermore, prior to the provision of a package, a fifth substrate and a fifth interface layer may be provided on the stack of layers and substrates. Furthermore, a sixth substrate and a sixth interface layer may be provided on top of the fifth interface layer. In general, arrangements of 2n substrates and/or 2n+1 substrates are possible embodiments of the present invention. The integrated circuit may be provided as a dual die package (DDP).

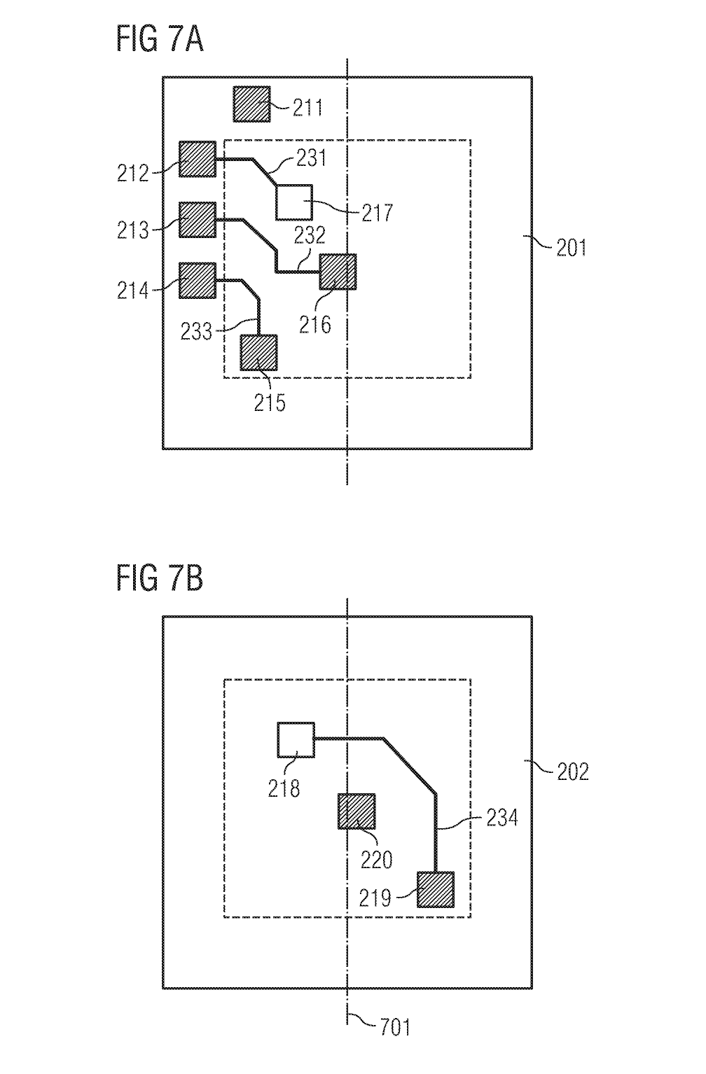

FIGS. 7A and 7B illustrate a schematic top view of interface layers according to an eighth embodiment of the present invention. FIG. 7A illustrates a schematic top view of a first interface layer 201. The interface layer 201 may be one of the interface layers 121 through 124 as described in conjunction with one of the FIGS. 1A through 6D and may include contact pads 211, 212, 213, 214, 215, 216, and 217. The contact pads 211 through 216, which are illustrated as black rectangles, may allow a contact from above, i.e. from the viewer's direction. The contact pad 217 however, illustrated as a white rectangle establishes a contact to a bottom surface of the interface layer 201, hence the contact pad 217 is isolated on the top surface. The interface layer 201 may include signal lines 231, 232, and 233. Furthermore, there may be contact pads being arranged in a rim area of the interface layer 201, such as the contact pads 211 through 214, whereas there may be contact pads being arranged in a center area of the interface layer 201, such as the contact pads 215 through 217. Arranging pads within a rim area may correspond to a wedge on chip technology.

As illustrated in FIG. 7B, a second interface layer 202 may include contact pads 218, 219 and 220. The interface layer 202 may further include a signal line 234, connecting the contact pad 218 to the contact pad 219. As already described in conjunction with FIG. 7A, the contact pads 219 and 220, which are illustrated as black rectangles, are accessible from the top surface of the interface layer 202, i.e. the viewer's direction. Correspondingly, the contact pad 218, illustrated as a white rectangle, is isolated from above. The contact pad 218 may be coupled to a further contact of a substrate which may be arranged underneath the second interface layer 202 at this respective position. Likewise, the contact pad 220 may contact a contact pad of the substrate lying essentially underneath the contact pad 220. A signal line is then arranged perpendicularly to the plane of the second interface layer 202, connecting an underlying contact pad to the facing contact pad 220.

The second interface layer 202, in conjunction with other elements, such as a substrate being attached to a bottom side of the interface layer 202, may be flipped upside down along an axis 701 and being arranged on the first interface layer 201. In this way, the contact pad 216 of the first interface layer 201, at least partially overlaps with the contact pad 220 of the second interface layer. Likewise the contact pad 215 of the first interface layer 201 at least overlaps with the contact pad 219 of the second interface layer 202. Establishing a contact between the contact pads 216 and 220, and the pads 215 and 219, respectively, then allows for a connection of the contact pad 218 to the contact pad 214, and a connection of the contact pad 220 to the contact pad 213. In this way, contacts being arranged in a center area of a substrate may be connected to contact pads in a rim area of the first interface layer 201, which may be easier accessible for further connection, for example by a bond wire. In general, the pads for connecting the second interface layer 202 to the first interface 201 layer may be arranged with respective positions that satisfy a mirror-symmetry condition, such that a pad of the second layer 202 at least overlaps with a respective path of the first layer 201, when the second layer 202 is flipped and faces the first layer 201. Furthermore, the respective lengths of the signal lines may be matched, in order to achieve an enhanced electrical performance.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a first substrate;
a first interface layer on the first substrate, the first interface layer comprising a first signal path;
a second interface layer on the first interface layer, the second interface layer comprising a second signal path, the second signal path being coupled to the first signal path; and
a second substrate on the second interface layer, the second substrate comprising an electronic device, the electronic device being coupled to the second signal path of the second interface layer.

2. The integrated circuit of claim 1, comprising a carrier substrate, the stack of substrates and layers being arranged on the carrier substrate, the carrier substrate comprising a first contact pad, the first interface layer comprising a second contact pad, the second contact pad being coupled to the first signal path and to the first contact pad.

3. The integrated circuit of claim 2, further comprising a bond wire, the bond wire connecting the first contact pad to the second contact pad.

4. The integrated circuit of claim 3, comprising wherein the second contact pad of the first interface layer being arranged on a surface of the first interface layer inside a surface rim area.

5. The integrated circuit of claim 1, further comprising an interconnection layer between the first interface layer and the second interface layer, the interconnection layer comprising a contact for connecting the first signal path to the second signal path.

6. The integrated circuit of claim 5, the interconnection layer comprising:
a solder connection;
a stud bump;
a conductive adhesive;
an anisotropic conductive adhesive;
an isolating material;
a dielectric material; and
a heat conductive material.

7. The integrated circuit of claim 1, comprising a further substrate and a further interface layer on the stack of substrates and layers.

8. The integrated circuit of claim 1, further comprising a further stack of a further first substrate, a further first interface layer, a further second interface layer, and a further second substrate on the stack of substrates and layers.

9. The integrated circuit of claim 8, comprising a further substrate and a further interface layer on the further stack of substrates and layers.

10. The integrated circuit of claim 1, further comprising a heat spreader on the stack of substrates and layers.

11. A memory device, comprising:
a first substrate;
a first interface layer on the first substrate, the first interface layer comprising a first signal path;
a second interface layer on the first interface layer, the second interface layer comprising a second signal path, the second signal path being coupled to the first signal path; and
a second substrate on the second interface layer, the second substrate comprising an electronic device, the electronic device being coupled to the second signal path of the second interface layer.

12. The memory device of claim 11, comprising:
a carrier substrate, the stack of substrates and layers being arranged on the carrier substrate;
a first contact pad, the first contact pad being arranged on the carrier substrate; a second contact pad, the second contact pad being arranged on a surface of the first contact pad;
interface layer inside a surface rim area and being coupled to the first signal path; a bond wire, the bond wire connecting the first contact pad to the second contact pad; and
a package, the package being arranged adjacent to the stack of substrates and layers, to the carrier substrate, and to the bond wire.

13. The memory device of claim 11, further comprising an interconnection layer between the first interface layer and the second interface layer, the interconnection layer comprising at least one of the following:
a solder connection for connecting the first signal path to the second signal path;
a stud bump for connecting the first signal path to the second signal path;
conductive adhesive for connecting the first signal path to the second signal path;
an anisotropic conductive adhesive for connecting the first signal path to the second signal path;
an isolating material;
dielectric material; and
heat conductive material.

14. The memory device of claim 11, comprising a further substrate and a further interface layer on the stack of substrates and layers.

15. The memory device of claim 11, further comprising a further stack of a further first substrate, a further first interface layer, a further second interface layer, and a further second substrate on the stack of substrates and layers.

16. The memory device of claim 15, comprising a further substrate and a further interface layer on the further stack of substrates and layers.

17. The memory device of claim 11, further comprising a heat spreader on the stack of substrates and layers.

18. The memory device of claim 11, the first substrate and the second substrate being electronic memory chips comprising an array of memory cells.

19. A memory module, comprising a circuit board and a memory device, comprising:
a first substrate on the circuit board;
a first interface layer on the first substrate, the first interface layer comprising a first signal path;
a second interface layer on the first interface layer, the second interface layer comprising a second signal path, the second signal path being coupled to the first signal path; and
a second substrate on the second interface layer, the second substrate comprising an electronic device, the electronic device being coupled to the second signal path of the second interface layer,
the first signal path being coupled to the circuit board.

20. The memory module of claim 19, the circuit board comprising a first contact pad, the first interface layer comprising a second contact pad, and the memory device comprising a bond wire, the bond wire connecting the first contact pad and the second contact pad.

21. The memory module of claim 19, the memory device comprising a carrier substrate and a bond wire, the stack of substrates and layers being arranged on the carrier substrate, the carrier substrate comprising a first contact pad, and the first interface layer comprising a second contact pad, the bond wire connecting the first contact pad and the second contact pad.

22. The memory module of claim 21, the carrier substrate comprising a third contact pad, the circuit board comprising a fourth contact pad, and the memory module comprising a solder connection, the solder connection connecting the third contact pad and the fourth contact pad.

23. The memory module of claim 21, the memory device comprising a package, the package being arranged adjacent to the stack of substrates and layers and adjacent to the carrier substrate.

24. The memory module of claim 19, the memory device comprising a package, the package being arranged adjacent to the stack of substrates and layers and adjacent to the circuit board.

25. The memory module of claim 19, the memory device comprising an interconnection layer, the interconnection layer being arranged between the first interface layer and the second interface layer.

26. The memory module of claim 19, the memory device comprising a further substrate and a further interface layer on the stack of substrates and layers.

27. The memory module of claim 19, the memory device further comprising a further stack of a further first substrate, a further first interface layer, a further second interface layer, and a further second substrate on the stack of substrates and layers.

28. The memory module of claim 27, the memory device comprising a further substrate and a further interface layer on the further stack of substrates and layers.

29. The memory module of claim 19, the memory device further comprising a heat spreader on the stack of substrates and layers.

30. The memory module of claim 19, the circuit board being a printed circuit board comprising an interconnection terminal with a row of contact pads.

31. A circuit system comprising an integrated circuit and a circuit board, comprising:
a first substrate on the circuit board;
a first interface layer on the first substrate, the first interface layer comprising a first signal path;
a second interface layer on the first interface layer, the second interface layer comprising a second signal path, the second signal path being coupled to the first signal path; and
a second substrate on the second interface layer, the second substrate comprising an electronic device, the electronic device being coupled to the second signal path of the second interface layer,
the first signal path being coupled to the circuit board.

32. The system of claim 31, the integrated circuit comprising a further substrate and a further interface layer on the stack of substrates and layers.

33. The system of claim 31, the integrated circuit comprising a further stack of a further first substrate, a further first interface layer, a further second interface layer, and a further second substrate on the stack of substrates and layers.

34. The system of claim 33, the integrated circuit comprising a further substrate and a further interface layer on the further stack of substrates and layers.

35. A method of fabricating an integrated circuit, comprising:
providing a first substrate;
providing a first interface layer on the first substrate, the first interface layer comprising a first signal path;
providing a second substrate, the second substrate comprising an electronic device; providing a second interface layer on the second substrate, the second interface layer comprising a second signal path, the second signal path being coupled to the electronic device of the second substrate;
stacking the first substrate with the first interface layer and the second substrate with the second interface layer, such that the first interface layer is arranged on the second interface layer; and
establishing a contact between the first signal path and the second signal path.

36. The method of claim 35, further comprising:
providing a carrier substrate, the carrier substrate comprising a contact pad;
placing the first substrate with the first interface layer on the carrier substrate before stacking the substrates; and
contacting the first signal path of the first interface layer to the contact pad of the carrier substrate.

37. The method of claim 36, the contacting of the first signal path to the contact pad comprising a bonding of a bond wire to the contact pad of the carrier substrate and to a further contact pad being coupled to the first signal path.

38. The method of claim 35, the method further comprising:
providing an interconnection layer between the first interface layer and the second interface layer before stacking the substrates.

39. The method of claim 38, the providing of the interconnection layer comprising at least one of the following:
providing a solder ball;
providing a solder paste;
providing a stud bump;
providing a conductive adhesive;
providing an anisotropic conductive adhesive;
providing an isolating material;
providing a dielectric material; and
providing a heat conductive material.

40. The method of claim 39, the establishing of a contact further comprising:
a heating of the stack of substrates and layers.

41. The method of claim 35, further comprising:
providing a further substrate and a further interface layer on the stack of substrates and layers.

42. The method of claim 35, further comprising:
providing a further stack of a further first substrate, a further first interface layer, a further second interface layer, and a further second substrate on the stack of substrates and layers.

43. The method of claim 42, further comprising:
providing a further substrate and a further interface layer on the further stack of substrates and layers.

44. The method of claim 35, further comprising:
providing a heat spreader on the stack of substrates and layers.

45. The method of claim 35, further comprising:
providing a packaging material adjacent to the stack of substrates and layers.

46. An integrated circuit comprising:
a first substrate;
means for providing a first interface layer on the first substrate, the first interface layer means comprising a first signal path;
means for providing a second interface layer on the first interface layer means, the second interface layer comprising a second signal path, the second signal path being coupled to the first signal path; and
means for providing a second substrate on the second interface layer means, the second substrate means comprising an electronic device, the electronic device being coupled to the second signal path of the second interface layer.
